(19) United States
(12) Patent Application Publication
(10) Pub. No.: US 2011/0122592 A1
(43) Pub. Date: May 26, 2011

(54) First-level interconnects with slender columns, and processes of forming same

(76) Inventors: Sanka Ganesan, Chandler, AZ (US); Richard J. Harries, Chandler, AZ (US); Sujit Sharan, Chandler, AZ (US)

(21) Appl. No.: 12/592,395

(22) Filed: Nov. 24, 2009

(51) Int. Cl. H05K 7/02; H01L 21/60; H01L 23/488; H01L 23/48

(52) U.S. Cl. 361/767; 438/121; 257/779; 257/692; 257/773; 257/E21.509; 257/E23.01; 257/E23.023

(57) ABSTRACT

A column is coupled to a last metallization of a die and the column is mated to a mounting substrate with that aid of a solder. The column may have the solder attached thereto before mating to the mounting substrate and the mounting substrate may be a bare-board (no solder mask) during the mating process. The column has an aspect ratio between 0.75 and 10.

Disclosed embodiments relate to semiconductor microelectronic devices and processes of packaging them.

### BRIEF DESCRIPTION OF THE DRAWINGS

In order to understand the manner in which embodiments are obtained, a more particular description of various embodiments briefly described above will be rendered by reference to the appended drawings. These drawings depict embodiments that are not necessarily drawn to scale and are not to be considered to be limiting in scope. Some embodiments will be described and explained with additional specificity and detail through the use of the accompanying drawings in which:

FIG. 1a is a cross-section elevation of an apparatus that includes a die and mounting substrate during a mating process according to an example embodiment;

FIG. 1b is a cross-section elevation of the apparatus depicted in FIG. 1a after further processing according to an embodiment;

FIG. 2a is a cross-section elevation of an apparatus that includes a die and mounting substrate during a mating process according to an example embodiment;

FIG. 2b is a cross-section elevation of the apparatus depicted in FIG. 2a after further processing according to an embodiment;

FIG. 3a is a cross-section elevation of an apparatus that includes a die and mounting substrate during a mating process according to an example embodiment;

FIG. 3b is a cross-section elevation of the apparatus depicted in FIG. 3a after further processing according to an embodiment;

FIG. 4a is a cross-section elevation of an apparatus that includes a die and mounting substrate during a mating process according to an example embodiment;

FIG. 4b is a cross-section elevation of the apparatus depicted in FIG. 4a after further processing according to an embodiment;

FIG. 4c is a cross-section elevation of an apparatus that includes a die and mounting substrate during a mating process according to an example embodiment;

FIG. 5a is a cross-section elevation of an apparatus that includes a die and mounting substrate during a mating process according to an example embodiment;

FIG. 5b is a cross-section elevation of the apparatus depicted in FIG. 5a after further processing according to an embodiment;

FIG. 6 is a cross-section elevation of an apparatus that includes a die and mounting substrate according to an example embodiment;

FIG. 7 is a computer-reproduction image of a microphotograph according to an example embodiment;

FIG. 8 is a computer-reproduction image of a micrograph of die metallization and a mounting substrate according to an example embodiment;

FIG. 9 is a computer-reproduction image of a micrograph of die metallization and a mounting substrate according to an example embodiment;

FIG. 10 is a process flow diagram according to several embodiments; and

FIG. 11 is a schematic of a computer system according to an embodiment.

### DETAILED DESCRIPTION

Reference will now be made to the drawings wherein like structures may be provided with like suffix reference designations. In order to show the structures of various embodiments more clearly, the drawings included herein are diagrammatic representations of integrated circuit structures. Thus, the actual appearance of the fabricated integrated circuit structures, for example in a photomicrograph, may appear different while still incorporating the claimed structures of the illustrated embodiments. Moreover, the drawings may only show the structures useful to understand the illustrated embodiments. Additional structures known in the art may not have been included to maintain the clarity of the drawings.

A “bare board” is defined as a mounting substrate that during a chip-mating process, has no solder resist or equivalent surrounding bond pads on the mounting substrate. A “column” is defined as a bump that is attached to a die active surface that has an aspect ratio (height-to-width) of greater than 0.75 and that generally has a free end during a chip-mating process. The column may have a solder covering the free end. The column is substantially straight and has a vertical (Z-dimension) orientation that is orthogonal to the active surface of the die. A “last metallization” is defined as the intra-die metallization connection for a die before communication to the outside as conventionally understood. For example, the last metallization served conventionally as the bond pad for a die. The last metallization serves as a foundation contact for a column. A “wide base” is an extension of the last metallization and it contacts the column. The wide base is defined as having an aspect ratio of 0.5 or less. Consequently, the wide base may be recognized as having a form factor that is orthogonal to that of the column.

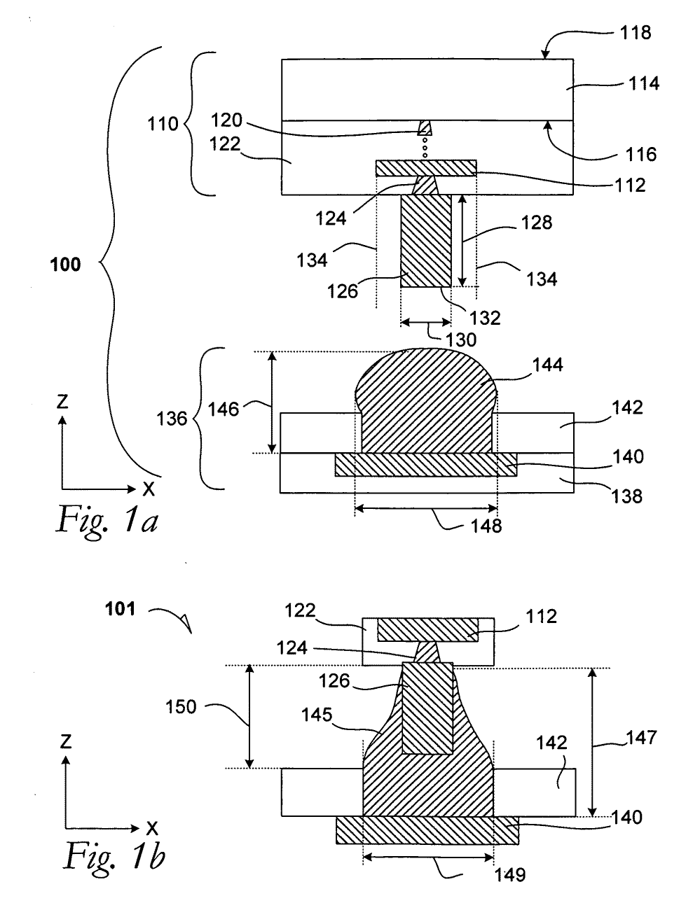

FIG. 1a is a cross-section elevation of an apparatus that includes a die 110 and mounting substrate 136 during a mating process 100 according to an example embodiment. The process 100 illustrates that the die 110 has a last metallization 112 such as a metal-9 (M9) as is understood in the art. In an embodiment, the last metallization 112 is less than M9 depending upon the application, and it can be any last metallization between M1 and M8.

The die 110 may be a processor such as any processor made by Intel Corporation of Santa Clara, Calif. In an embodiment, the die 110 is a memory die. In an embodiment, the die 110 is a system-on-chip (SOC) die. In an embodiment, the die 110 is an application-specific integrated circuit (ASIC). The die 110 includes a semiconductive substrate 114 with active and passive devices disposed at an active surface 116. The die 110 includes a backside surface 118 that is opposite the active surface 116. Communication to the active surface 116 is made such as by a contact 120 that may couple to, e.g., M1 and ultimately to the last metallization 112 such as an M9 last metallization 112. The entire metallization is enclosed in several interlayer dielectric layers, which are illustrated for simplicity as a metallization ILD structure 122. It is understood, however, that the metallization ILD structure 122 may be composed of several individual ILD layers that are built up incidental to completing the metallization.

The last metallization 112 has a last contact 124 that breaches the ILD structure 122 and makes contact to a column 126. It may also be understood that the last contact 124 may be omitted and the column 126 formed directly upon the last metallization 112 to make contact with the last metallization 112.

The column 126 has an aspect ratio of height 128 (Z-dimension) divided by width 130 (X-dimension). In an embodiment, the column 126 has an aspect ratio in a range from 0.75 to 10. In an embodiment, the column 126 has an aspect ratio in a range from 0.8 to 10. In an embodiment, the column 126 has an aspect ratio in a range from 1.1 to 3. In an embodiment, the column 126 has an aspect ratio in a range from 1.2 to 1.8.

In an embodiment, the column 126 has a width between 10 μm and 80 μm, and is any of the disclosed aspect-ratio embodiments set forth in this disclosure. This column-width range is contemplated for all disclosed embodiment in this disclosure.

The column 126 exhibits an exposed and free end 132 that is defined as having no material touching at this surface 132 during mating to a mounting substrate according to an embodiment. In an embodiment, the column 126 has a width that is less than the width of the last metallization 112 such that the last metallization 112 has edge projections 134 that encompass the column in the X-dimension. This structural feature wherein the width of the last metallization 112 exceeding the width of the column 126, provides a significant stress relief to the ILD structures of the die 110, after the die attachment to the mounting substrate 136.

The process 100 also illustrates the mating action of the die 110 to a mounting substrate 136. The mounting substrate 136 is illustrated to include a printed wiring board 138 that includes a board bond pad 140 that is exposed through a solder mask 142 according to an embodiment. A board solder bump 144 is disposed upon the board bond pad 140. The board solder bump 144 has an aspect ratio that is defined by the bump height 146 divided by the bump width 148. It can be seen that the bump width 148 may exceed the dimension of the solder resist open formed by the solder mask 142. In an embodiment, the aspect ratio of the board solder bump 144 is in a range from 0.1 to 9.

In an embodiment, the critical dimension of the structures is the width (X-dimension) of the last metallization 112. The critical dimension is in a range from 10 micrometer (μm) to 100 μm according to an embodiment. For this critical dimension range, the height 128 of the column 126 is in a range from 60 μm to 90 μm and the width of the column 126 is in a range from 10 μm to 60 μm.

Usually, the column 126 is made from copper and the board solder bump 144 is a reflowable solder material according to an embodiment. The composition of the solder bump 144 includes metallurgies (pure metal, binary alloys, ternary or quaternary alloys or combinational solder bump including a stack of solder bumps with different compositions with decreasing melting temperatures from the bottom of the board solder bump 144) known in the art. For example these can include pure Sn, Sn37 wt. % Pb, Sn3 wt % Ag0.5 wt. % Cu, Sn0.7 wt. % Cu, Sn3.5 wt % Ag, Sn 57 wt. % In, Sn52 wt. % Bi Sn9 wt. % Zn,

The bond pad 140 can be Copper or Ni—Au coated Cu , Pd—Ni—Au coated Copper, Sn coated Copper, or Silver coated Copper, as known in the art. The solder material for 144 can be designed to achieve desired temperature of attachment for the semiconductor device (die) to the board. In an embodiment, the material for the column 126 is Copper. In an embodiment, the material for the column 126 is a high melting-point solder material like pure Sn (melting point about 232° C., Sn0.7 wt. % Cu (melting point about 227° C.) or Sn3.5 wt. % Ag (melting point about 221° C.).

FIG. 1b is a cross-section elevation of the apparatus depicted in FIG. 1a after further processing according to an embodiment. The apparatus 101 is depicted in simplified details for clarity. After the mating process of bringing the free end 132 (FIG. 1a) into the board solder bump 144 (FIG. 1a) the column 126 shows that the board solder bump 145 exhibits a wetting action such that much or all of the column 126 has been wetted by the board solder bump 145. The board solder bump 145 has an aspect ratio of height 147 to width 149 that relates by comparison to the height 146 and width 148 seen in FIG. 1a. Further by completing mating of the die 110 to the mounting substrate 136, there remains an offset 150 between die and mounting substrate that may be filled such as with an underfill material. The column 126 now is electrically coupled between the die 110 and the mounting substrate 136.

As a result of the combined aspect ratio of the column 126 and the offset 150 mating disparities among irregular topographies between a die and a mounting substrate are resolved in favor completing the bonds without creating non-useful open contacts. Another result of the combined aspect ratio of the column height, ILD peel stress is decreased which makes more useful package integrity for the apparatus 101 For example, a 2× reduction in the ILD peel stress can be achieved by using a column architecture with a width of 10 μm and a height of 90 μm. Moreover ILD crack energy release rate can be decreased significantly with the interconnect design in which the width of the last metallization 112 overhangs the width of the copper column 126. Thus for example, the width of the last metallization 112 can be about 60 μm and the width/height of the copper column 126 can be 40 μm/80 μm, respectively

In some designs, where the width of the last metallization 112 can not be designed to be wider than the width of the copper column 126, an extra plating process can be performed to provide a “wide base” which can be designed/processed with the width overhanging the width of the copper column 126. This embodiment also provided significant ILD stress-spreading utility and also allows for larger diameter columns or wider ranges of aspect ratios.

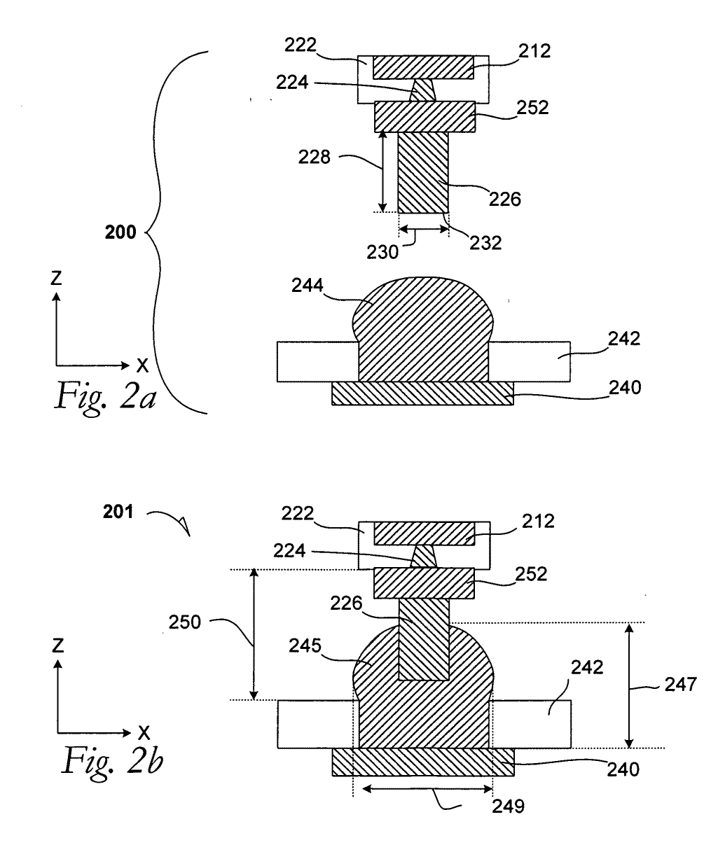

FIG. 2a is a cross-section elevation of an apparatus that includes a die and mounting substrate during a mating process 200 according to an example embodiment. The process 200 is illustrated in simplified form similarly to FIG. 1b. The die has a last metallization 212 such as an M9 as is understood in the art. In an embodiment, the last metallization 212 is less than M9 depending upon the application, and it can be any last metallization between M1 and M8.

The entire metallization is enclosed in several interlayer dielectric layers, which are illustrated for simplicity as a metallization ILD structure 222. It is understood, however, that the metallization ILD structure 222 may be composed of several individual ILD layers that are built up incidental to completing the metallization.

The last metallization 212 has a last contact 224 that breaches the ILD structure 222 and makes contact to a wide base 252, which in turn makes contact to a column 226. The wide base 252 is similar in electrical wiring function as the last metallization 212 in that it has no other connection to the balance of the die except through the last metallization 212. In other words, the wide base 252 has last metallization functionality with respect to electrical coupling. The wide base 252 reduces stress on the die compensating for larger stress transfer of a smaller dia. column above 20 um and the column adds flexibility to the bond between the die and the mounting substrate.

The column 226 has any aspect ratio of the column 126 depicted and described in FIGS. 1a and 1b. Consequently, the wide base 252 may be recognized as having a form factor that is orthogonal to that of the column 226. The column 226 exhibits an exposed and free end 232 that is defined as having no material touching at this surface 232 during mating to a mounting substrate according to an embodiment. In an embodiment, the column 226 has a width that is less than the width of the last metallization 212.

The process 200 also illustrates the mating action of the die to a mounting substrate. The mounting substrate is illustrated in simplified form that includes a board bond pad 240 that is exposed through a solder mask 242 according to an embodiment. A board solder bump 244 is disposed upon the board bond pad 240. The board solder bump 244 has an aspect ratio that is defined by the bump height divided by the bump width.

In an embodiment, the critical dimension of the structures is the width (X-dimension) of the last metallization 212. The critical dimension is in a range from 10 micrometer (μm) to 30 μm according to an embodiment. For this critical dimension range, the height 228 of the column 226 is in a range from 60 μm to 90 μm.

The column 226 is made usually from copper and the board solder bump 244 is a reflowable solder material according to an embodiment. The composition of the solder bump 244 includes metallurgies (pure metal, binary alloys, ternary or quaternary alloys or combinational solder bump consisting of stack of solder bumps with different compositions with decreasing melting temperatures from the bottom of the board solder bump 244) known in the art. For example these can include pure Sn, Sn37 wt. % Pb, Sn3 wt % Ag0.5 wt. % Cu, Sn0.7 wt. % Cu, Sn3.5 wt % Ag, Sn 57 wt. % In, Sn52 wt. % Bi Sn9 wt. % Zn etc.

The bond pad 240 can be Copper or Ni—Au coated Cu, Pd—Ni—Au coated Copper, Sn coated Copper, or Silver coated Copper, as known in the art. The solder material for 244 can be selected to achieve desired temperature of attachment for the semiconductor device (die) to the board. In an embodiment, the material for the column 226 is Copper. In an embodiment, the material for the column 226 is a high melting-point solder material like pure Sn (melting point about 232° C., Sn0.7 wt. % Cu (melting point about 227° C.) or Sn3.5 wt. % Ag (melting point about 221° C.), which does not melt during attachment process.

FIG. 2b is a cross-section elevation of the apparatus depicted in FIG. 2a after further processing according to an embodiment. The apparatus 201 is depicted in simplified details for clarity. After the mating process of bringing the free end 232 (FIG. 2a) into the board solder bump 244 (FIG. 2a) the column 226 shows that the board solder bump 245 exhibits less wetting action than that depicted in FIG. 2b according to an example embodiment. The degree of wetting may be a function of reflow temperatures as well as the different metallurgies of the column 226 and the board solder bump 245. By comparison to wetting depicted in FIG. 1b, wetting depicted in FIG. 2b may be less and affected by processing conditions and/or materials. The board solder bump 245 may have a different aspect ratio than that of the solder board bump 145 depicted in FIG. 1b, assuming all other conditions are similar between the two structures.

The board solder bump 245 has an aspect ratio of height 247 to width 249 that may be different or the same as the aspect ratio of the board solder bump 244 depicted in FIG. 2a. Further by completing mating of the die to the mounting substrate, there remains an offset 250 between die and mounting substrate that may be filled such as with an underfill material.

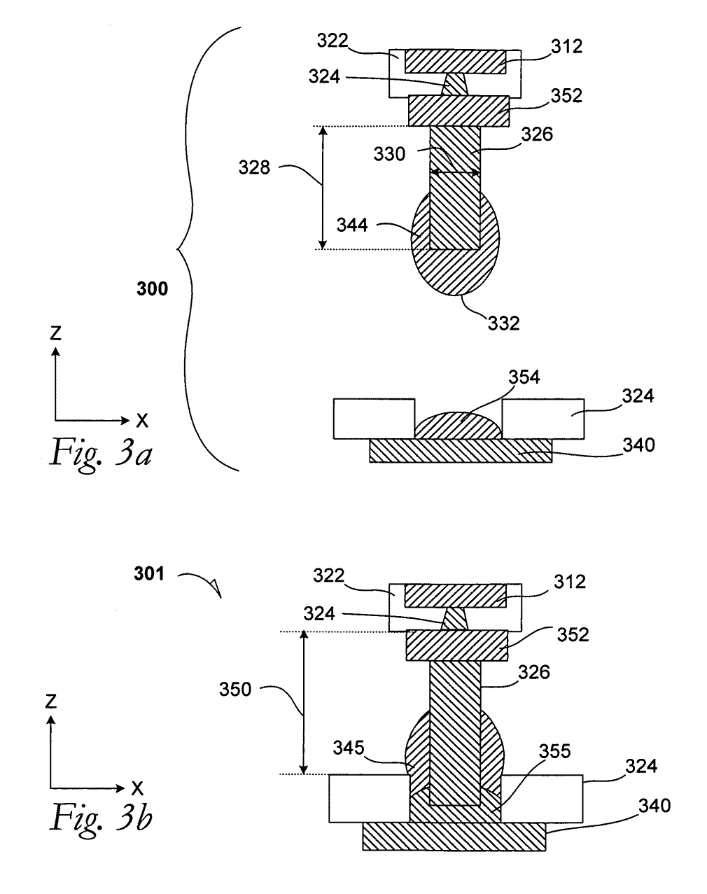

FIG. 3a is a cross-section elevation of an apparatus that includes a die and mounting substrate during a mating process 300 according to an example embodiment. The process 300 is illustrated in simplified form similarly to FIGS. 1b, 2a, and 2b. The die has a last metallization 312 such as an M9 as is understood in the art. In an embodiment, the last metallization 312 is less than M9 depending upon the application, and it can be any last metallization between M1 and M8.

The entire metallization is enclosed in several interlayer dielectric layers, which are illustrated for simplicity as a metallization ILD structure 322. It is understood, however, that the metallization ILD structure 322 may be composed of several individual ILD layers that are built up incidental to completing the metallization.

The last metallization 312 has a last contact 324 that breaches the ILD structure 322 and makes contact to a wide base 352, which in turn makes contact to a column 326. The wide base 352 is similar in electrical wiring function as the last metallization 312 in that it has no other connection to the balance of the die except through the last metallization 312. The column 326 has any aspect ratio of the column 126 depicted and described in FIGS. 1a and 1b. The column 326 is encumbered with a board solder bump 344 and together the column 326 and the board solder bump precursor 344 exhibit an exposed and free end 332 that is defined as having no material touching at this surface 332 during mating to a mounting substrate according to an embodiment. Formation of the solder bump precursor 344 may be done by dipping the column 326 into a fluent solder-paste mass such as a heated mass that cools and agglomerates to the column 326 as the board solder bump 344. Other methods of forming the board solder bump precursor 344 onto the column 362 include electro deposition, solder paste printing, micro-ball deposition process or vapor agglomeration onto the column 326 to form the solder bump 344.

In an embodiment, the column 326 has a width that is less than the width of the last metallization 312.

The process 300 also illustrates the mating action of the die to a mounting substrate. The mounting substrate is illustrated in simplified form that includes a board bond pad 340 that is exposed through a solder mask 342 according to an embodiment. A board solder bump 354 is disposed upon the board bond pad 340 according to an embodiment. In an embodiment, the board solder bump 354 is not present and the solder bump 344 is the only solder material to be used during mating of the die and mounting substrate.

In an embodiment, the critical dimension of the structures is the width (X-dimension) of the last metallization 312. The critical dimension is in a range from 10 μm to 60 μm according to an embodiment. For this critical dimension range, the height 328 of the column 326 is in a range from 60 μm to 90 μm.

The column 326 is made from copper and the solder bump 344 is a lead-free solder material according to an embodiment. In an embodiment, the board solder bump 354 is the same material and composition as the solder bump 344. In an another embodiment, the board solder bump 354 melting temperature is greater than the melting temperature of the solder bump 344 material. For example, the board solder bump 354 contains Sn0.7 wt. % Cu solder (melting point about 227° C.), and the solder bump precursor 344 contains a Sn57wt. % In solder material (melting point about 120° C.). This tempearure hierarchy provides for the ability to attach the semiconductor device to the board at a low temperature (about 120° C.) and thus can reduce the thermal stress on the semiconductor device.

The composition of the solder bump 354 includes metallurgies (pure metal, binary alloys, ternary or quaternary alloys) known in the art. For example these can include pure Sn, Sn37 wt. % Pb, Sn3 wt % Ag0.5 wt. % Cu, Sn0.7 wt. % Cu, Sn3.5 wt % Ag, Sn9 wt. % Zn etc. The bond pad 340 can be Copper or Ni—Au coated Cu, Pd—Ni—Au coated Copper, Sn coated Copper, or Silver coated Copper, as known in the art. The solder material for 344 can be designed to achieve desired temperature of attachment for the semiconductor device to the board. In an embodiment, the material for the column 326 is Copper. In an embodiment, the material for the column 326 is a high melting point solder material like pure Sn (melting point about 232° C., Sn0.7 wt. % Cu (melting point about 227° C.) or Sn3.5 wt. % Ag (melting point about 221° C.), which does not melt during attachment process

FIG. 3b is a cross-section elevation of the apparatus depicted in FIG. 3a after further processing according to an embodiment. The apparatus 301 is depicted in simplified details for clarity. The mating process has formed a board solder bump portion 355 that is derived from the board solder bump 354, and a board solder bump 345 that is derived from the solder bump r 344. The board solder bump portion 355 may have a metallurgy that is more like that of the board bond pad 340 than that of the column 326, and the board solder bump 354 may have a metallurgy that is more like that of the column 326 than that of the board bond pad 340. This embodiment facilitates a stronger bonding between column 362 and board bond pad 340 and also a more flexible structure in the column 326 and board solder bump 345. Although there is illustrated a distinct line between the board solder bump portion 355 and the board solder bump 345, it is understood that reflow processing may cause a concentration gradient to form in the boundary therebetween.

After the mating process of bringing the free end 332 (FIG. 3a) to contact the mounting substrate at the board bond pad 340, the column 326 shows that the board solder bump 345 exhibits a wetting action. The degree of wetting may be a function of reflow temperatures as well as the different metallurgies of the column 326, the board solder bump 345, and the board solder bump 354 (FIG. 3a) if present. Wetting may be affected by processing conditions and/or materials.

By completing mating of the die to the mounting substrate, there remains an offset 350 between die and mounting substrate that may be filled such as with an underfill material.

In an embodiment, the processes depicted in FIGS. 3a and 3b are carried out without the presence of a wide base 352.

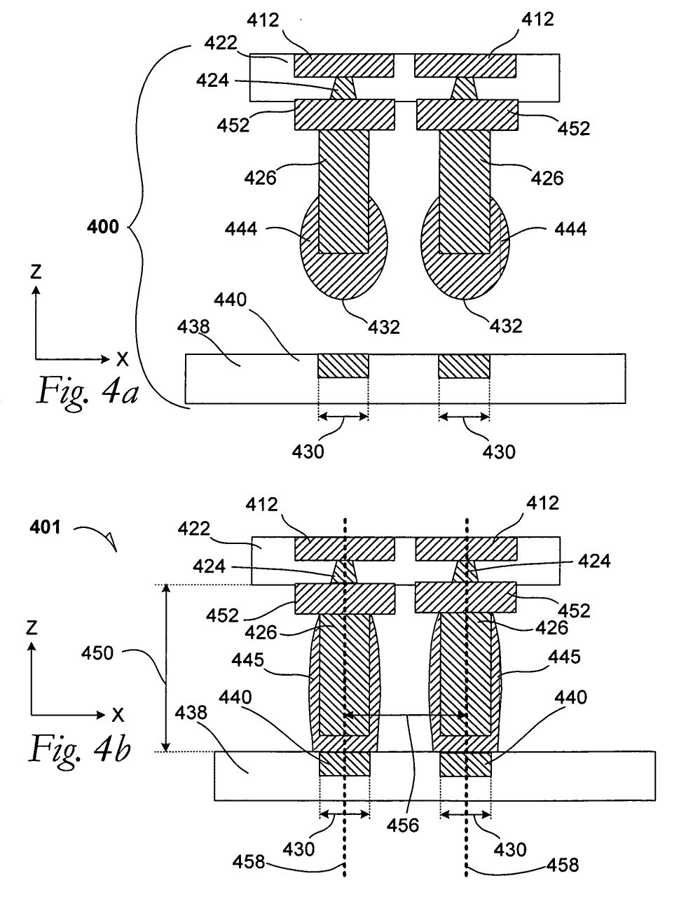

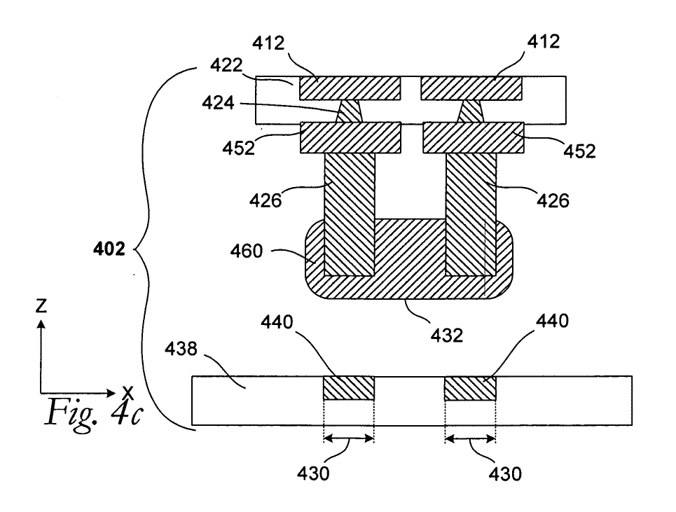

FIG. 4a is a cross-section elevation of an apparatus that includes a die and mounting substrate during a mating process 400 according to an example embodiment. The process 400 is illustrated in simplified form similarly to FIGS. 1b, 2a, 2b, 3a, and 3b. The process depicts, however a plurality of bonding sites according to this embodiment. The die has a last metallization 412 such as an M9 as is understood in the art. In an embodiment, the last metallization 412 is less than M9 depending upon the application, and it can be any last metallization between M1 and M8.

The entire metallization is enclosed in several interlayer dielectric layers, which are illustrated for simplicity as a metallization ILD structure 422. It is understood, however, that the metallization ILD structure 422 may be composed of several individual ILD layers that are built up incidental to completing the metallization.

The last metallization 412 has a last contact 424 that breaches the ILD structure 422 and makes contact to a wide base 452, which in turn makes contact to a column 426. The wide base 452 is similar in electrical wiring function as the last metallization 412 in that it has no other connection to the balance of the die except through the last metallization 412. The column 426 has any aspect ratio of the column 126 depicted and described in FIGS. 1a and 1b. The column 426 is encumbered with a solder bump 444 and together the column 426 and the solder bump 444 exhibit an exposed and free end 432 that is defined as having no material touching at this surface 432 during mating to a mounting substrate 438 according to an embodiment. In an embodiment, the column 426 has a width that is less than the width of the last metallization 412.

The process 400 also illustrates the mating action of the die to a mounting substrate 438. The mounting substrate 438 is illustrated to include a board bond pad 440, but no solder mask is present according to an embodiment. This configuration is referred to as “bare board” 438 or “bare mounting substrate” 438. In an embodiment, no board solder bump is present and the solder bump 444 is the only solder material to be used during mating of the die and mounting substrate.

In this embodiment, the lateral dimension (X-dimension) of the board bond pad 440 is smaller than in any illustrations depicted in previous FIGs. The width 430 of the board bond pad 440 is given to be the same as the column 426 for an illustrative embodiment. The width 430 can be smaller or larger than that of the column 426.

In an embodiment, the critical dimension of the structures is the width (X-dimension) of the last metallization 412 and the width of the wide base 452. The critical dimension for 412 is in a range from 10 μm to 30 μm according to an embodiment. The width of the wide base 452 is in a range from 30 μm to 90 μm. For this critical dimension range, the width of the column 426 is in a range from 10 μm to 60 μm and the height of the column 426 is in a range from 60 μm to 90 μm. The selection of the critical dimensions for 452 and 426 can be designed to a particular product.

The column 426 is made from copper and the solder bump 444 is Sn0.5 wt. % Cu in an embodiment. In an embodiment, the board solder bump, if present, is the same material and composition as the solder bump 444.

The composition of the solder bump 444 includes metallurgies (pure metal, binary alloys, ternary or quaternary alloys) known in the art. For example these can include pure Sn, Sn37 wt. % Pb, Sn3 wt % Ag0.5 wt. % Cu, Sn0.7 wt. % Cu, Sn3.5 wt % Ag, Sn9 wt. % Zn etc. The bond pad 440 can be Copper or Ni—Au coated Cu, Pd—Ni—Au coated Copper, Sn coated Copper, or Silver coated Copper, as known in the art. The solder material for 444 can be designed to achieve desired temperature of attachment for the semiconductor device (die) to the board. In an embodiment, the material for the column 326 is Copper. In an embodiment, the material for the column 326 is a high melting point solder material like pure Sn (melting point about 232° C., Sn0.7 wt. % Cu (melting point about 227° C.) or Sn3.5 wt. % Ag (melting point about 221° C.), which does not melt during attachment process.

FIG. 4b is a cross-section elevation of the apparatus depicted in FIG. 4a after further processing according to an embodiment. The apparatus 401 is depicted in simplified details for clarity. After the mating process of bringing the free end 432 (FIG. 4a) to contact the bare board 438 at the board bond pad 440, the column 426 shows that the board solder bump 445 exhibits a wetting action. The degree of wetting may be a function of reflow temperatures as well as the different metallurgies of the column 426, the board solder bump 445, and the board solder bump if present. Wetting may be affected by processing conditions and/or materials. It can be seen as illustrated that wetting the column 426 by the board solder bump 445 causes the solder 445 to wet the column 426 to the column at the end opposite the free end.

It can be seen that a bare board 438 does not have the encumbrance of a solder mask such that tighter pitches between adjacent columns 426 can be accomplished. Pitch 456 is determined from center-to-center between two adjacent columns 426 as measured from the symmetry lines 458 as illustrated in this cross-sectional elevation. Where an embodiment includes pitch 456 to be a function of width 430 and spacing between two adjacent columns 426, wetting action of the board solder bump 445 allows for tighter pitches without significant occurrences of bridging between adjacent solder bumps 445. Where the two adjacent columns may be referred to as a first column 426 and a second column 426 adjacent the first column 426, and where the second column 426 has the same aspect ratio as the first column 426. In most applications, the aspect ratios of the columns is the same all across the die. In one embodiment, a variable aspect ratio exists (by having variable width for the columns 426 and with the same height) for the columns 426 across the die

Due to wetting action during reflow, as illustrated in this embodiment at FIG. 4b, the adjacent solder bumps 445 have become smaller in width (X-dimension) than prior to reflow as depicted in FIG. 4a.

Where the solder bump 444 (FIG. 4a) is pre-attached to the column 426, the processes of depositing the solder to the mounting substrate 438 can be eliminated. In some applications, masking the mounting substrate 438 is eliminated because there is no requirement to register, pattern, and etch a solder resist.

By completing mating of the die to the mounting substrate, there remains an offset 450 between die and mounting substrate that may be filled such as with an underfill material.

FIG. 4c is a cross-section elevation of an apparatus that includes a die and mounting substrate during a mating process 402 according to an example embodiment. The process depicts a plurality of bonding sites according to this embodiment and a solder bump sheet 460 in the place of solder bump 444 depicted in FIG. 4a. The structures in FIG. 4c are otherwise similar to the structures depicted in FIG. 4a

The process 402 illustrates the mating action of the die to a bare-board mounting substrate 438. The bare-board configuration is where no solder mask is needed on the mounting substrate during mating of the die and the mounting substrate. Reflow processing is such that the solder bump sheet 460 has a greater affinity to wetting the columns 426 and the board bond pads 440 than the bare-board mounting substrate 438. In an embodiment, wetting of the bare-board mounting substrate 438 is resisted. Consequently, reflow results in no solder remaining in touch with the bare-board mounting substrate 438 as seen in FIG. 4b to a sufficient degree that bridging of solder between adjacent columns is resisted. It can now be appreciated that the solder bump sheet 460 may be laid up on the bare-board mounting substrate 438 and the columns 426 mated thereto and that reflow of the solder resulting in a structure similar to that illustrated in FIG. 4b.

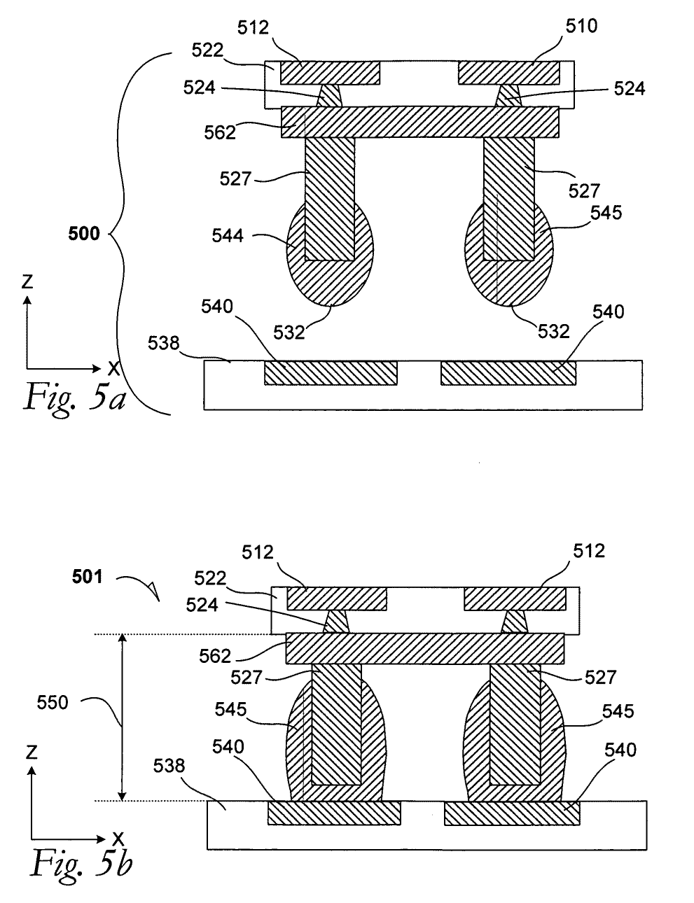

FIG. 5a is a cross-section elevation of an apparatus that includes a die and mounting substrate during a mating process 500 according to an example embodiment. The process depicts a plurality of bonding sites according to this embodiment and a wide base 562 that shunts a plurality of columns 527 such as for a power-delivery portion of a die. The shunted wide base 562 ties more than one column together to assist in redistributing the high current-flow electrical draw. The die has a last metallization 512 such as an M9 as is understood in the art. In an embodiment, the last metallization 512 is less than M9 depending upon the application, and it can be any last metallization between M1 and M8.

The entire metallization is enclosed in several interlayer dielectric layers, which are illustrated for simplicity as a metallization ILD structure 522. The last metallization 512 has a last contact 524 that breaches the ILD structure 522 and makes contact to the shunted wide base 562, which in turn makes contact to the columns 527. The columns 527 have any aspect ratio of the column 126 depicted and described in FIGS. 1a and 1b. The columns 527 are encumbered with a board solder bump 544 and together the columns 527 and the board solder bump 544 exhibit an exposed and free end 532.

In an embodiment, the column 527 has a width that is less than the width of the last metallization 512. In an embodiment, the column 527 has a width that is less than the width of the of the unshunted wide base 562

The process 500 also illustrates the mating action of the die to a mounting substrate 538. The mounting substrate 538 is illustrated to include a board bond pad 540, but no solder mask is present according to an embodiment. This configuration is referred to as “bare board” 538 or “bare mounting substrate” 538. In an embodiment, a solder mask is present on the mounting substrate 538 similar to embodiments depicted in FIGS. 1, 2, and 3. In an embodiment, no board solder bump is present and the board solder bump precursor 544 is the only solder material to be used during mating of the die and mounting substrate 538.

FIG. 5b is a cross-section elevation of the apparatus depicted in FIG. 5a after further processing according to an embodiment. The apparatus 501 is depicted in simplified details for clarity. After the mating process of bringing the free end 532 (FIG. 5a) to contact the bare board 538 at the board bond pad 540, the column 527 shows that the board solder bump 545 exhibits a wetting action. The degree of wetting may be a function of reflow temperatures as well as the different metallurgies of the column 527, the board solder bump 545, and the resistance to wetting of the bare board 538, among other disclosed factors and embodiments. Wetting may be affected by processing conditions and/or materials.

By completing mating of the die to the mounting substrate, there remains an offset 550 between die and mounting substrate that may be filled such as with an underfill material.

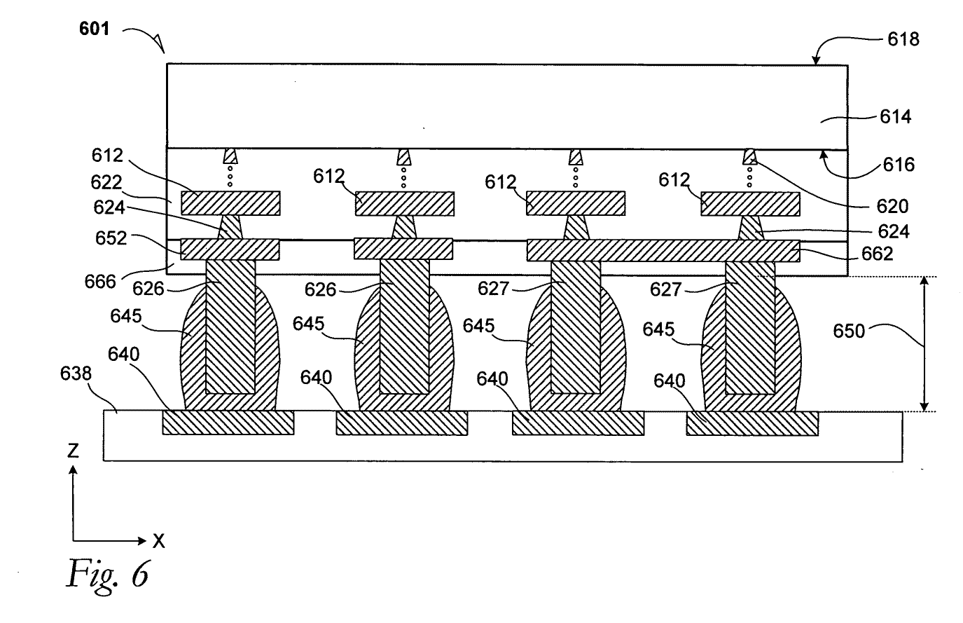

FIG. 6 is a cross-section elevation of an apparatus that includes a die and mounting substrate according to an example embodiment. A plurality of bonding sites 640 (one enumerated), a plurality of wide bases 652 (one enumerated) and that contact a plurality of columns 626, and a wide base 662 that shunts a plurality of columns 627 such as for a power-delivery portion of a die. The wide base 662 may be referred to as a first wide base 662, and the wide base 652 that is adjacent and spaced apart from the first wide base 662 may be referred to as a subsequent wide base 652.

The apparatus 601 may be referred to as a chip-package apparatus 601. The shunted wide base 662 ties more than one column together to assist in redistributing the high current-flow electrical draw. The die has a last metallization 512 such as an M9 as is understood in the art. In an embodiment, the last metallization 512 is less than M9 depending upon the application, and it can be any last metallization between M1 and M8.

The die includes a semiconductive substrate 614 with an active surface 616 and a backside surface 618 that is opposite the active surface 616. Communication to the active surface 616 is made such as by a contact 620 that may couple to, e.g., M1 and ultimately to the last metallization 612 such as an M9 last metallization 612. A significant portion of the metallization is enclosed in several interlayer dielectric layers, which are illustrated for simplicity as a metallization ILD structure 622. It is understood, however, that the metallization ILD structure 622 may be composed of several individual ILD layers that are built up incidental to completing the metallization.

One portion of the apparatus 601 includes the last metallization 612 with a last contact 624 that breaches the ILD structure 662 and makes contact with a wide base 652. Further as illustrated, one portion of the apparatus 601 includes the last metallization 612 with a last contact 624 that breaches the ILD structure 622 and makes contact to a shunted wide base 662, which in turn makes contact to columns 627. The columns 626 and 627 have any aspect ratio of the column 126 depicted and described in FIGS. 1a and 1b.

A cap film 666 is formed over the wide base 652 and the shunted wide base 662. It is understood that the cap film 666 embodiment may be located on a die with only the wide base 652 embodiments and not the shunted wide-base 662 embodiments.

The mounting substrate 638 is illustrated to include a plurality of board bond pads 640, but no solder mask is present according to an embodiment. This configuration is referred to as “bare board” 638 or “bare mounting substrate” 638. In an embodiment, a solder mask is present on the mounting substrate 638 similar to embodiments depicted in FIGS. 1, 2, and 3.

After the mating process of reflowing the solder 645 between the column 526 and the board bond pad 640, the column 626 shows that the board solder bump 645 exhibits a wetting action. By completing mating of the die to the mounting substrate 638, there remains an offset 650 between die and mounting substrate that may be filled such as with an underfill material.

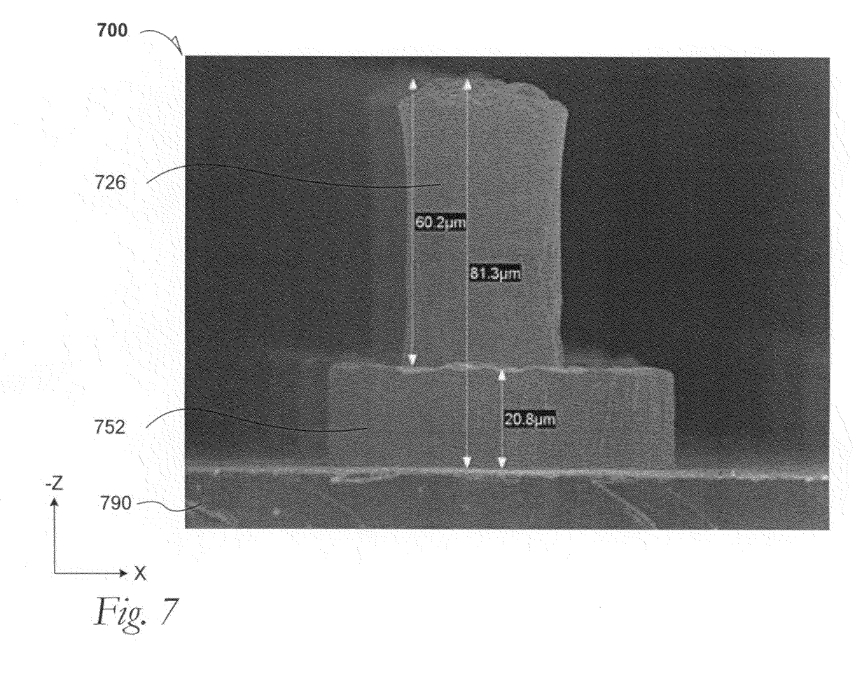

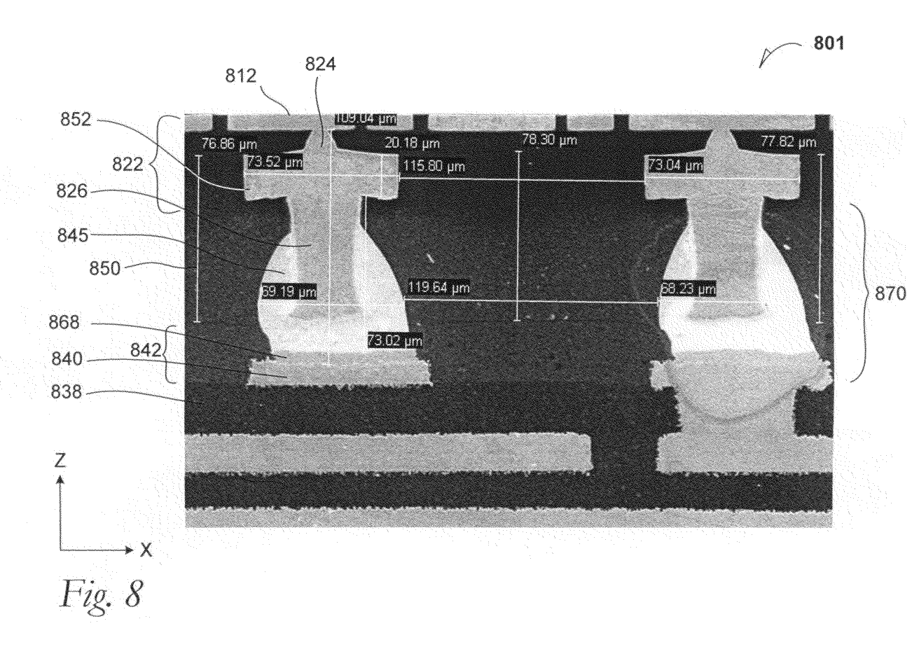

FIG. 7 is a computer-reproduction image of a microphotograph 700 according to an example embodiment. A wide base 752 was formed on a substrate 790, and a column 726 was formed on the wide base 752. The column 726 has an aspect ratio of about 2 in this illustrated embodiment.

FIG. 8 is a computer-reproduction image of a micrograph 801 of die metallization and a mounting substrate according to an example embodiment. The micrograph 801 is a representation of a chip-package apparatus 801. A last metallization 812 is depicted such as an M9 as is understood in the art. In an embodiment, the last metallization 812 is less than M9 depending upon the application, and it can be any last metallization between M1 and M8. Communication from active surface of a die to the last metallization 812 is made by a last contact 824 that breaches an ILD structure 822.

The last metallization 812 and last contact 824 are coupled to a column 826 through contact with a wide base 852. The column 826 had an aspect ratio of about 2. The column 826 has a width that is less than the width of the last metallization 812 such that the edges of the last metallization 812 projecting in the Z-dimension encompass the column in the X-dimension. In this embodiment, the width of the column 826 is less than the width of wide base 852 also.

The column 826 was mated to a board 838. The board 838 is illustrated to include a printed wiring board that includes a board bond pad 840 that was exposed through a solder mask 842. The board bond pad 840 was also treated to have a metal flash layer 868 for a protective film. The metal flash layer 868 may be a material such as nickel or nickel-gold. A board solder bump 845 is disposed upon the flash layer 868. The board solder bump 845 has an aspect ratio that is defined by the bump height divided by the bump width. It can be seen that the bump width may exceed the dimension of the solder resist open formed by the solder mask 842.

FIG. 8 also shows that the board solder bump 845 exhibits a wetting action such that much or all of the column 826 has been wetted by the board solder bump 845. Further by completing mating of the column 826 to the board bond pad 840, there remains an offset 850 between die and mounting substrate that was filled with an underfill material 870. The offset 850 is depicted as being between about 76 μm and 78 μm.

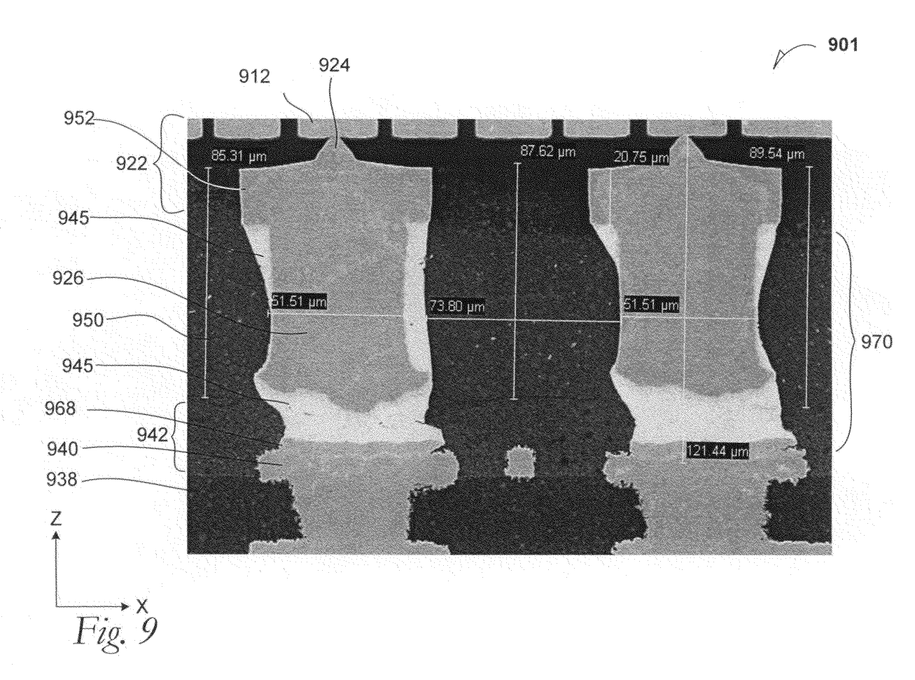

FIG. 9 is a computer-reproduction image of a micrograph 901 of die metallization and a mounting substrate according to an example embodiment. The micrograph 901 is a representation of a chip-package apparatus 901. A last metallization 912 is depicted such as an M9 as is understood in the art. In an embodiment, the last metallization 912 is less than M9 depending upon the application, and it can be any last metallization between M1 and M8. Communication from active surface of a die to the last metallization 912 is made by a last contact 924 that breaches an ILD structure 922.

The last metallization 912 and last contact 924 are coupled to a column 926 through contact with a wide base 952. The column 926 had an aspect ratio of about 1.5. The column 926 has a width that is less than the width of the wide base 952 such that the edges of the last metallization 912 projecting in the Z-dimension encompass the column in the X-dimension.

The column 926 was mated to a board 938. The board 938 is illustrated to include a printed wiring board that includes a board bond pad 940 that was exposed through a solder mask 942. The board bond pad 940 was also treated to have a metal flash layer 968 for a protective film. A board solder bump 945 is shown to have effectively wetted the entire column 826 from the flash layer 968 to the wide base 952. As a consequence of processing conditions including at least one of solder wetting affinity to the column 926 and temperature, the board solder bump 945 has an aspect ratio that is defined principally by the dimensions of the column 926, the volume of material available in the board solder bump 945 before reflow, and processing conditions.

By completing mating of the column 926 to the board bond pad 940, there remains an offset 950 between die and mounting substrate that was filled with an underfill material 970. The offset 950 is depicted as being between about 85 μm and 90 μm.

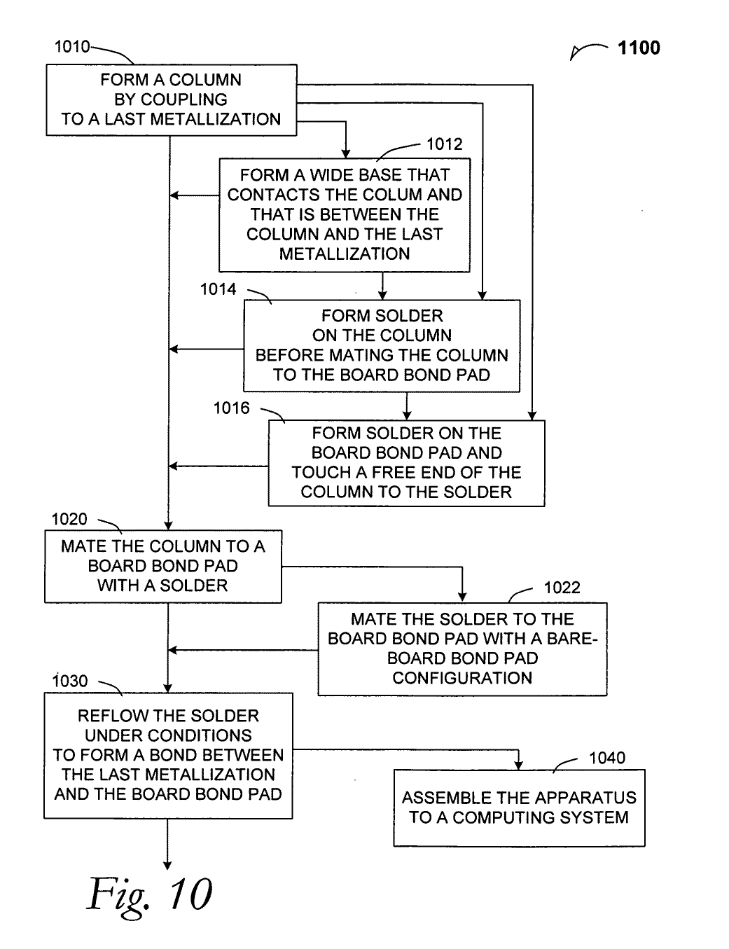

FIG. 10 is a process flow diagram according to several embodiments.

At 1010, the process includes forming a column by coupling it to a last metallization. Coupling has been depicted in this disclosure through a last via such as the last contact 124 depicted in FIG. 1a. It may now be understood that the column may also be formed directly upon the last metallization by omitting the last contact.

At 1012, the process includes forming a wide base before coupling a column to the last metallization. In a non-limiting example embodiment, the wide base 852 was formed, followed by the column 826, such that the last metallization 812 was coupled to the column 826 through the wide base 852. It may also be understood that that a cap film such as the cap film 666 may be formed over the wide base 652.

At 1014, the process includes forming the solder on the column before touching the free end of the column and solder bump precursor to the board bond pad. In a non-limiting example embodiment, the free end 332 of the solder bump precursor 344 is mated to the board bond pad 340 while the solder bump precursor 344 is attached to the column 326. The free end 332 of the column 326 is understood to include the solder bump precursor 344 that has no contact at this location.

At 1016, the process includes forming solder on the board bond pad and touching a free end of the column to the solder. In a non-limiting example embodiment, the free end 132 of the column 126 is touched to the board solder bump 144 to form the board solder bump 145. In a non-limiting example embodiment, the solder bump precursor sheet 460 is first laid up on the mounting substrate 438 and the column 426 first touches the solder bump precursor sheet 460 that already has made contact with the board bond pad 440.

At 1020, the process includes mating the column to a board bond pad with a solder.

At 1022, the process includes mating the solder to the board bond pad with a bare-board configuration. In a non-limiting example embodiment, the solder bump precursor 444 is sufficiently small in volume and lateral (X-dimension) size that bare-board solder reflow is carried out. It can now be appreciated that process 1022 may be skipped by forming the solder through a solder mask open that exposes the board bond pad through the solder mask open.

At 1030, the process includes reflowing the solder bump under conditions to form a bond between the last metallization and the board bond pad. Reflow conditions may include wetting metallurgy, time, and temperature among others. It may now be understood that an underfill process such as forming the underfill 870 may follow reflow or it may precede reflow where the underfill is sufficiently fluent not to disturb the board solder bump prior to reflow.

At 1040, a method includes assembling the apparatus, formed by any process described herein, to a computer system.

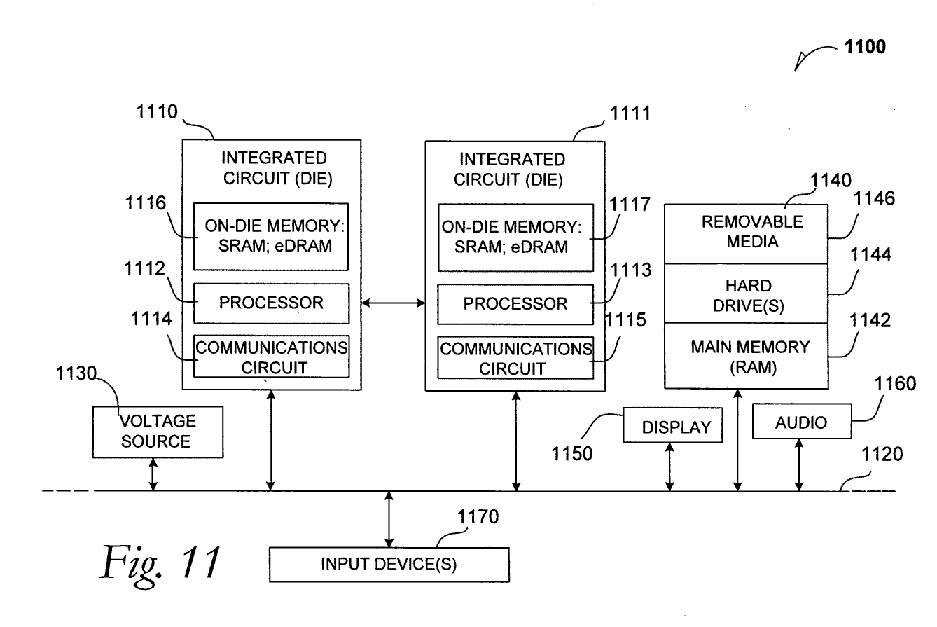

FIG. 11 is a schematic of a computer system 1100 according to an embodiment. The computer system 1100 (also referred to as the electronic system 1100) as depicted can embody a wetted column and solder bump with a chip and mounting substrate apparatus according to any of the several disclosed embodiments and their equivalents as set forth in this disclosure. The computer system 1100 may be a mobile device such as a netbook computer. The computer system 1100 may be a mobile device such as a wireless smart phone.

In an embodiment, the electronic system 1100 is a computer system that includes a system bus 1120 to electrically couple the various components of the electronic system 1100. The system bus 1120 is a single bus or any combination of busses according to various embodiments. The electronic system 1100 includes a voltage source 1130 that provides power to the integrated circuit 1110. In some embodiments, the voltage source 1130 supplies current to the integrated circuit 1110 through the system bus 1120.

The integrated circuit 1110 is electrically coupled to the system bus 1120 and includes any circuit, or combination of circuits according to an embodiment. In an embodiment, the integrated circuit 1110 includes a processor 1112 that can be of any type. As used herein, the processor 1112 may mean any type of circuit such as, but not limited to, a microprocessor, a microcontroller, a graphics processor, a digital signal processor, or another processor. In an embodiment, SRAM embodiments are found in memory caches of the processor. Other types of circuits that can be included in the integrated circuit 1110 are a custom circuit or an application-specific integrated circuit (ASIC), such as a communications circuit 1114 for use in wireless devices such as cellular telephones, pagers, portable computers, two-way radios, and similar electronic systems. In an embodiment, the processor 1110 includes on-die memory 1116 such as static random-access memory (SRAM). In an embodiment, the processor 1110 includes embedded on-die memory 1116 such as embedded dynamic random-access memory (eDRAM).

In an embodiment, the integrated circuit 1110 is doubled dual integrated circuit 1111. The dual integrated circuit 1111 includes a dual processor 1113 and a dual communications circuit 1115 and dual on-die memory 1117 such as SRAM. In an embodiment, the dual integrated circuit 1110 includes embedded on-die memory 1117 such as eDRAM.

In an embodiment, the electronic system 1100 also includes an external memory 1140 that in turn may include one or more memory elements suitable to the particular application, such as a main memory 1142 in the form of RAM, one or more hard drives 1144, and/or one or more drives that handle removable media 1146, such as diskettes, compact disks (CDs), digital variable disks (DVDs), flash memory drives, and other removable media known in the art. The external memory 1140 may also be embedded memory 1148 such as the wetted column and solder bump with a chip and mounting substrate apparatus according to an embodiment.

In an embodiment, the electronic system 1100 also includes a display device 1150, an audio output 1160. In an embodiment, the electronic system 1100 includes an input device such as a controller 1170 that may be a keyboard, mouse, trackball, game controller, microphone, voice-recognition device, or any other input device that inputs information into the electronic system 1100. In an embodiment, an input device 1170 is a camera. In an embodiment, an input device 1170 is a digital sound recorder. In an embodiment, an input device 1170 is a camera and a digital sound recorder.

As shown herein, the integrated circuit 1110 can be implemented in a number of different embodiments, including a wetted column and solder bump with a chip and mounting substrate apparatus according to any of the several disclosed embodiments and their equivalents, an electronic system, a computer system, one or more methods of fabricating an integrated circuit, and one or more methods of fabricating an electronic assembly that includes a wetted column and solder bump with a chip and mounting substrate apparatus according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed wetted column and solder bump with a chip and mounting substrate apparatus embodiments and their equivalents.

Although a chip may refer to a processor chip or a memory chip or that may be mentioned in the same sentence, it should not be construed that they are equivalent structures. Reference throughout this disclosure to “one embodiment” or “an embodiment” means that a particular feature, structure, or characteristic described in connection with the embodiment is included in at least one embodiment of the present invention. The appearance of the phrases “in one embodiment” or “in an embodiment” in various places throughout this disclosure are not necessarily all referring to the same embodiment. Furthermore, the particular features, structures, or characteristics may be combined in any suitable manner in one or more embodiments.

Terms such as “upper” and “lower” “above” and “below” and “vertical” may be understood by reference to the illustrated X-Z coordinates, and terms such as “adjacent” and “horizontal” may be understood by reference to X-Y coordinates or to non-Z coordinates.

The Abstract is provided to comply with 37 C.F.R. §1.72(b) requiring an abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate preferred embodiment.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

What is claimed is:

1. An apparatus, comprising:
a microelectronic chip including an active surface side and including metallization, wherein the metallization terminates in a bond pad and a column coupled to the bond pad, wherein the column has an aspect ratio between 0.75 and 10, and wherein the column includes a free end.

2. The apparatus of claim 1, further including a solder bump attached to the column and wherein the free end is the solder bump.

3. The apparatus of claim 1, further including a wide base disposed between the last metallization and the column, wherein the wide base contacts the column.

4. The apparatus of claim 1, wherein the column is a first column, the apparatus further including:
a second column adjacent and spaced apart from the first column; and
a wide base disposed between the last metallization and the first- and second columns, wherein the wide base is shunted between the first- and second columns.

5. The apparatus of claim 1, wherein the column is a first column, the apparatus further including:
a second column adjacent the first column wherein the second column has the same aspect ratio as the first column.

6. The apparatus of claim 1, wherein the column is a first column, the apparatus further including:
a second column adjacent the first column wherein the second column has the same aspect ratio as the first column, and wherein the second column is spaced apart from the first column by a distance from 1.2 times and larger the column width.

7. The apparatus of claim 1, further including a mounting substrate, wherein the mounting substrate includes a board bond pad that is aligned with the column.

8. The apparatus of claim 1, further including:
a mounting substrate, wherein the mounting substrate includes a board bond pad that is aligned with the column; and
a solder precursor aligned with the column and the board bond pad.

9. The apparatus of claim 1, further including:
a mounting substrate, wherein the mounting substrate includes a board bond pad that is aligned with the column;
a solder precursor aligned with the column and the board bond pad; and
wherein the mounting substrate is a bare-board configuration.

10. A chip-package apparatus, comprising:
a microelectronic chip including an active surface side and including metallization, wherein the metallization terminates in a bond pad and a wire coupled to the bond pad, wherein the wire has an aspect ratio between 0.75 and 10;
a mounting substrate, wherein the mounting substrate includes a board bond pad that is bonded with the column, and wherein the board bond pad is a bare-board bond pad.

11. The chip-package apparatus of claim 10, further including a solder bump attached to the column and the board bond pad.

12. The chip-package apparatus of claim 10, further including a wide base disposed between the last metallization and the column, wherein the wide base contacts the column.

13. The chip-package apparatus of claim 10, wherein the column is a first column, the apparatus further including:
a second column adjacent and spaced apart from the first column; and
a wide base disposed between the last metallization and the first- and second columns, wherein the wide base is shunted between the first- and second columns.

14. The chip-package apparatus of claim 10, wherein the column is a first column, the apparatus further including:
a second column adjacent and spaced apart from the first column;
a first wide base disposed between the last metallization and the first- and second columns, wherein the first wide base is shunted between the first- and second columns; and
a subsequent column spaced apart and adjacent the second column, and
a subsequent wide base disposed between the last metallization and the subsequent columns, wherein the subsequent wide base is spaced apart from the first wide base.

15. The chip-package apparatus of claim 10, wherein the column is a first column, the apparatus further including:
a second column adjacent the first column wherein the second column has the same aspect ratio as the first column, and wherein the second column is spaced apart from the first column by a distance from 1.2 times and larger the column width.

16. A process comprising:
forming a column by coupling to a last metallization of a chip, wherein the column has an aspect ratio between 0.75 and 10;
mating the chip at a free end of the column to a board bond pad with solder; and reflowing the solder.

17. The process of claim 16, further including forming a wide base between the last metallization and the column, wherein the wide base has last metallization functionality, and wherein the wide base contacts the column.

18. The process of claim 16, further including forming the column directly upon the last metallization to contact the last metallization.

19. The process of claim 16, wherein forming the solder on the column is done before mating the column to the board bond pad.

20. The process of claim 16, wherein forming the solder on the column is done before mating the column to the board bond pad, and wherein mating the chip to the board bond pad is done with a bare-board bond pad.

21. The process of claim 16, wherein mating the chip at a free end of the column to the board bond pad is preceded by forming the solder on the board bond pad and touching the column free end to the solder.

22. The process of claim 16, wherein reflowing the solder causes the solder to wet the column to the column at the end opposite the free end.

23. The process of claim 16, wherein the column is a first column and wherein a second column is adjacent and spaced apart from the first column, and wherein the solder is a sheet that covers the first column and the second column.

24. The process of claim 16, wherein the column is a first column and wherein a second column is adjacent and spaced apart from the first column, the process further including contacting the first- and second columns to a wide base that is coupled to chip last metallization and that is shunted between the first- and second columns.

25. The process of claim 16, wherein the column is a first column and wherein a second column is adjacent and spaced apart from the first column, wherein the solder is a sheet that covers the first column and the second column and wherein mating the chip to the board bond pad is done with a bare-board bond pad.

26. The process of claim 16, wherein the solder is formed on the column by dipping the column into a solder mass and withdrawing therefrom to form a solder bump.

27. A computer system with a semiconductive device comprising:
a microelectronic chip including an active surface side and including metallization, wherein the metallization terminates in a bond pad and a wire coupled to the bond pad, wherein the wire has an aspect ratio between 0.75 and 10;
a mounting substrate, wherein the mounting substrate includes a board bond pad that is bonded with the column, and wherein the board bond pad is a bare-board bond pad; and
external memory coupled to the microelectronic chip.

28. The computer system of claim 27, wherein the wire is a first wire, the system further including:
a second wire adjacent and spaced apart from the first wire; and
a wide base disposed between the last metallization and the first- and second wires, wherein the wide base is shunted between the first- and second wires.

29. The computer system of claim 27, wherein the column is a first column, the system further including:
a second column adjacent and spaced apart from the first column;
a first wide base disposed between the last metallization and the first- and second columns, wherein the first wide base is shunted between the first- and second columns; and
a subsequent column spaced apart and adjacent the second column, and
a subsequent wide base disposed between the last metallization and the subsequent column, wherein the subsequent wide base is spaced apart from the first wide base.

30. The computing system of claim 27, wherein the computing system is part of one of a cellular telephone, a pager, a portable computer, a desktop computer, and a two-way radio.
